(19) United States
(12) Patent Application Publication
(10) Pub. No.: US 2022/0270792 A1
(43) Pub. Date: Aug. 25, 2022

(54) FE-BASED SOFT MAGNETIC ALLOY, METHOD FOR MANUFACTURING SAME, AND MAGNETIC COMPONENT COMPRISING SAME

(71) Applicant: AMOGREENTECH CO., LTD., Gimpo-si, Gyeonggi-do (KR)

(72) Inventors: Se Joong YOON, Gimpo-si, Gyeonggi-do (KR); Soon Mo HWANG, Gimpo-si, Gyeonggi-do (KR); Yong Sul SONG, Gimpo-si, Gyeonggi-do (KR)

(73) Assignee: AMOGREENTECH CO., LTD., Gimpo-si, Gyeonggi-do (KR)

(21) Appl. No.: 17/626,327

(22) PCT Filed: Jul. 13, 2020
(86) PCT No.: PCT/KR2020/009210

§ 371 Date: Jan. 11, 2022

(30) Foreign Application Priority Data
Jul. 12, 2019 (KR) 10-2019-0084514
Jul. 12, 2019 (KR) 10-2019-0084515

(51) Int. Cl. H01F 1/147; C22C 38/16; H01F 1/153; H01F 41/02; H01F 1/20

(52) U.S. Cl. CPC H01F 1/14708; C22C 38/16; C22C 2202/02; H01F 41/0253; H01F 1/20; H01F 1/15308

(57) ABSTRACT

Provided is a Fe-based soft magnetic alloy. A Fe-based soft magnetic alloy according to an embodiment of the present invention is expressed by the empirical formula FeₐB_{b}C_{c}Cu_{d}Nbₑ, wherein a, b, c, d, and e represent atomic percents (at %) of corresponding elements and satisfy 78.0≤a≤84.5 and 15.5≤b+c+d+e≤22.0. Hence, the Fe-based soft magnetic alloy has a high saturated magnetic flux density and high permeability characteristics and thus can be utilized for small and lightweight components, and has low coercive force and low magnetic loss characteristics and thus very easily finds applications in high-performance/high-efficiency components. Furthermore, the Fe-based soft magnetic alloy can minimize the effect of heat treatment conditions in the implementation of uniform grains with a small particle diameter after heat treatment, thereby greatly facilitating the design of process conditions, and thus is very suitable in mass production. Therefore, the Fe-based soft magnetic alloy can be widely applied to magnetic components of electric and electronic devices for a high-power laser, a high-frequency power supply, a high-speed pulse generator, SMPS, a high-frequency filter, a low-loss high-frequency transformer, a high-speed switch, wireless power transmission, electromagnetic wave shielding, and the like.

### CROSS REFERENCE TO RELATED APPLICATIONS

This application is a 35 U.S.C. 371 National Phase Entry Application from PCT/KR2020/009210, filed Jul. 13, 2020, which claims the benefit of Korean Patent Application Nos. 10-2019-0084514 and 10-2019-0084515 filed on Jul. 12, 2019, the disclosures of which are incorporated herein in their entirety by reference.

### TECHNICAL FIELD

The present invention relates to a Fe-based soft magnetic alloy, a method of manufacturing the same, and a magnetic part including the same.

### BACKGROUND

Soft magnetic materials are magnetic core materials for various types of transformers, choke coils, sensors, saturable reactors and magnetic switches, and widely used in various electrical and electronic devices for supplying or converting electric power, such as a distribution transformer, a laser power supply or an accelerator. In such electrical and electronic fields, the market for soft magnetic materials demands a small size, a light weight, high performance/high efficiency and a low product cost, and to satisfy such market demands, research on soft magnetic materials with a high saturation magnetic flux density and a low magnetic loss is being actively conducted.

Meanwhile, recently, other than the saturation magnetic flux density and the magnetic loss, there is a growing demand for a soft magnetic material with excellent magnetic permeability (hereinafter, permeability). However, it was difficult for Fe-based soft magnetic materials known so far to satisfy all characteristics such as a high saturation magnetic flux density, a low coercive force, a low magnetic loss and a high permeability. In addition, while such Fe-based soft magnetic materials are employed in parts for several uses, when the shape and size of a magnetic body are changed or the structure of a magnetic body is changed by flake treatment for compensating for an inherent physical property of magnetic materials, for example, magnetic loss upon employment, other physical properties can be greatly changed, so it is difficult for a magnetic material of a specific composition to be universally used in magnetic parts implemented for various uses or in various shapes and sizes.

Therefore, there is an urgent need to develop soft magnetic materials with a high saturation magnetic flux density, high permeability, and minimum magnetic loss and coercive force, which can be universally employed to various magnetic parts.

### SUMMARY OF THE INVENTION

The present invention has been devised in view of the above problems, and is directed to providing a Fe-based soft magnetic alloy which has a high saturation magnetic flux density, a maximum magnetic flux density and high permeability, and thus can be applied as a small, lightweight part, and has a low coercive force and a low magnetic loss and thus very easily used as parts with high performance/high efficiency, and a method of manufacturing the same.

The present invention is also directed to providing a Fe-based soft magnetic alloy, which has excellent saturation magnetic flux density and permeability, and low permeability loss even when the Fe-based soft magnetic alloy is implemented in various forms such as parts in the form of a magnetic core, and parts in the form of a flake-treated ribbon sheet, and a method of manufacturing the same.

The present invention is also directed to providing a Fe-based soft magnetic alloy which can minimize the effect of heat treatment conditions in the implementation of grains with uniform particle sizes after heat treatment.

Further, the present invention is also directed to providing a method of manufacturing a Fe-based soft magnetic alloy, which exhibits very suitable reproducibility for mass production, since soft magnetic alloys can be implemented to have uniform magnetic properties between them even when Fe-based soft magnetic alloys are repeatedly produced tens or hundreds of times under the same conditions

Moreover, the present invention is also directed to providing magnetic parts for various types of electrical and electronic devices used for functions of electromagnetic field shielding, energy supply and conversion and the like using a Fe-based soft magnetic alloy according to the present invention.

To solve the above-described problems, the present invention provides a Fe-based soft magnetic initial alloy represented by the empirical formula FeₐB_{b}C_{c}Cu_{d}Nbₑ. However, in the empirical formula, a, b, c, d and e represent the atomic percent (at %) of corresponding elements, respectively, and satisfy 78.0≤a≤84.5 and 15.5≤b+c+d+e≤22.0.

According to one embodiment of the present invention, the initial alloy may have an amorphous structure.

Also, in the empirical formula, a, b, c, d and e may satisfy 78.0≤a≤84.5, 12.5≤b≤17.0, 0.5≤c≤2, 0.5≤d≤1.2 and 0.8≤e≤3.0.

In the empirical formula, a and b may satisfy 79.0≤a≤82.0 and 14.04≤b≤17.0.

The value of Mathematical Formula 1 below with respect to a, b and e in the empirical formula may be in the range of 4.7 to 6.0.

$$\frac{a + e}{b} . \qquad [ Mathematical Formula 1 ]$$

In addition, the present invention provides a Fe-based soft magnetic alloy manufactured through heat treatment of the initial alloy represented by the empirical formula FeₐB_{b}C_{c}Cu_{d}Nbₑ. However, in the empirical formula, a, b, c, d and e represent the at % of corresponding elements, respectively, and satisfy 78.0≤a≤84.5 and 15.5≤b+c+d+e≤22.0.

According to one embodiment of the present invention, the Fe-based soft magnetic alloy may have an amorphous structure or grains with an average particle size of 60 nm or less in the amorphous matrix.

In addition, the grains may be included at 50 vol % or more, and more preferably, 50 to 70 vol % in the amorphous matrix. In addition, the average particle size may be 35 nm or less, and preferably 25 nm or less.

In addition, under conditions of 800 A/m and a magnetic field of 50 Hz, the Fe-based soft magnetic alloy may have a saturation magnetic flux density of 1.5 T or more, a coercive force of 10.0 A/m or less, and a core loss at IT and 50 Hz of 150 mW/kg or less.

In addition, the Fe-based soft magnetic alloy may be manufactured in the form of a ribbon sheet having predetermined thickness and width, or a magnetic core having predetermined outer diameter and inner diameter by winding the ribbon multiple times.

In addition, the permeability of the magnetic core formed of the Fe-based soft magnetic alloy at 100 kHz may be 3000 or more, and the real part of the complex permeability of the flaked magnetic sheet may be 1000 or more.

In addition, among the grains distributed from the surface to a depth of 5 μm, there may be no coarse grains having a particle size of more than 80 nm.

In addition, among the grains distributed from the surface to a depth of 5 μm, grains having a particle size of ±20% of the average particle size may account for 50% or more of the total grains.

In addition, the present invention provides a method of manufacturing a Fe-based soft magnetic alloy, which includes manufacturing a Fe-based initial alloy represented by the empirical formula FeₐB_{b}C_{c}Cu_{d}Nbₑ (here, a, b, c, d and e represent the at % of corresponding elements, 78.0≤a≤84.5, and 15.5≤b+c+d+e≤22.0), and thermally treating the Fe-based initial alloy.

According to one embodiment of the present invention, the heat treatment may include first heat treatment performed at a first heat treatment temperature higher than the crystallization initiation temperature (Tx₁) of the Fe-based initial alloy, and second heat treatment performed at a second heat treatment temperature lower than the first heat treatment temperature after the first heat treatment.

In addition, the first heat treatment temperature may be more than Tx₁° C. and less than or equal to (Tx₁+60) ° C., and the second heat treatment temperature may be (Tx₁−55° C.)˜(Tx₁+20° C.).

In addition, the first heat treatment may be performed for 2 to 30 minutes.

In addition, the second heat treatment may be performed for 5 to 70 minutes.

In addition, a temperature-increase rate up to the first heat treatment temperature may be 100° C./min or less.

In addition, a cooling rate from the first heat treatment temperature to the second heat treatment temperature may be 100° C./min or less.

In addition, after the second heat treatment, the Fe-based soft magnetic alloy may include nanograins having an average particle size of 60 nm or less.

In addition, the present invention provides an electromagnetic shielding material including the Fe-based soft magnetic alloy according to the present invention.

According to one embodiment of the present invention, the Fe-based soft magnetic alloy may be manufactured by laminating multiple pieces of a ribbon sheet in one or multiple layers.

In addition, the present invention provides a coil part including the Fe-based soft magnetic alloy according to the present invention and a coil winding around the Fe-based soft magnetic alloy.

Hereinafter, the terms used herein will be described.

The term “initial alloy” used herein refers to an alloy which does not undergo separate treatment for a change in properties of the manufactured alloy, for example, heat treatment.

In addition, the term “high frequency” used herein refers to a frequency band of several tens of kHz to several tens of MHz, for example, 50 kHz to 10 MHz.

### Advantageous Effects

According to the present invention, a Fe-based soft magnetic alloy has high saturation magnetic flux density and high permeability, so it can be used as small and lightweight parts, and has a low coercive force and a low magnetic loss, so it is very easily used as parts with high performance/high efficiency. In addition, the Fe-based soft magnetic alloy can minimize the effect of heat treatment conditions to implement grains with a small particle size after heat treatment, so it is easy to design process conditions and very suitable for mass production. Therefore, the Fe-based soft magnetic alloy can be widely applied to magnetic parts of electrical and electronic devices for a high-power laser, a high-frequency power supply, a high-speed pulse generator, SMPS, a high-frequency filter, a low-loss high-frequency transformer, a high-speed switch, wireless power transmission and electromagnetic wave shielding.

### BRIEF DESCRIPTION OF THE DRAWINGS

FIG. 1 is a graph for a temperature condition over time in heat treatment included in a manufacturing method according to one embodiment of the present invention.

FIG. 2 shows XRD patterns of Fe-based soft magnetic alloys of Examples 1 and 2 before heat treatment.

FIGS. 3 and 4 show an XRD pattern and a TEM image of a Fe-based soft magnetic alloy according to one embodiment of the present invention, respectively.

FIGS. 5 and 6 shows an XRD pattern and a TEM image of a Fe-based soft magnetic alloy according to one embodiment of the present invention, respectively.

FIG. 7 is a VSM graph of the Fe-based soft magnetic alloy according to FIGS. 3 and 4.

FIG. 8 is a VSM graph of the Fe-based soft magnetic alloy according to FIGS. 5 and 6.

FIG. 9 is the image of an apparatus for the flake treatment of a Fe-based soft magnetic alloy ribbon sheet according to one embodiment of the present invention.

FIGS. 10 and 11 are TEM images of a Fe-based soft magnetic alloy according to one embodiment of the present invention.

FIG. 12 is the image of an apparatus for measuring the permeability of a Fe-based soft magnetic alloy according to one embodiment of the present invention.

### DETAILED DESCRIPTION

Hereinafter, embodiments of the present invention will be described in detail so that those of ordinary skill in the art can easily carry out the present invention. However, the present invention may be implemented in a variety of different forms, and is not limited to the embodiments described herein.

A Fe-based soft magnetic initial alloy according to the present invention is an alloy represented by the empirical formula FeₐB_{b}C_{c}CuₐNbₑ, and in the empirical formula, a, b, c, d and e satisfy 78.0≤a≤84.5 and 15.5≤b+c+d+e≤22.0. Here, the a, b, c, d and e represent at % of corresponding elements.

First, Fe is the main element of a magnetic alloy, and to improve both saturation magnetic flux density and permeability, Fe may be included in the alloy at 78.0 at % or more, preferably 78.5 at % or more, more preferably 79 at % or more, and still more preferably 79.5 at % or more. When Fe is included at less than 78.0 at %, it may not be possible to achieve a desired level of saturation magnetic flux density. In addition, Fe may be included in the alloy at 84.5 at % or less, preferably 83 at % or less, and more preferably 82 at % or less, and when Fe is included in the alloy at more than 84.5 at %, the saturation magnetic flux density may increase, but it may be difficult to achieve a desired level of permeability. Particularly, in flake treatment, the real part of the permeability at high frequency may be dramatically reduced. In addition, as the contents of the remaining elements are relatively decreased according to an increasing content of Fe, upon liquid quenching for preparing the initial alloy, it may be difficult to prepare the crystalline phase of the initial alloy in an amorphous phase, and crystals generated in the initial alloy may interfere with uniform crystal growth in a heat treatment process for property change, and as the size of the generated crystals becomes excessively large, the coercive force may increase, and magnetic loss may also increase.

Next, B and C in the empirical formula are elements having amorphous forming ability, and may allow the initial alloy to be manufactured in an amorphous phase. In addition, as the C element is combined with the B element, compared to the case only including the B element, it is easy to control the grain size of generated α-Fe crystals to a desired level, and there is an advantage of obtaining uniform α-Fe crystals upon heat treatment by improving the thermal stability of the initial alloy. The sum of the B and C elements in the alloy is preferably 13.5 to 19.0 at %, and more preferably 15 to 19 at %. When the sum of the B and C elements is less than 13.5 at % in the alloy, it may be difficult to manufacture the manufactured initial alloy in an amorphous phase, the crystals in the initial alloy make the uniform growth of crystals generated in heat treatment for the change in magnetic properties difficult, and may include crystals with coarse particle sizes, thereby increasing the magnetic loss. In addition, when the sum of the B and C elements is more than 19.0 at %, the contents of the remaining components after heat treatment, that is, the content(s) of Cu and/or Nb, or the content of Fe may be decreased, and when the content(s) of Cu and/or Nb is(are) decreased, it may be difficult to grow grains to have a uniform particle size after heat treatment, or to achieve a desired level of permeability. In addition, when the Fe content is reduced, it may be difficult to exhibit desired levels of saturation magnetic flux density and permeability.

In one example, the B element may be included at 12.5 to 17 at % in the alloy, the C element may be included at 0.5 to 2 at %, and thus it may be easy to control the growth of grains in the alloy upon heat treatment, and advantageous for exhibiting a desired magnetic property. In addition, in another example, the B element may be included at 13 to 17 at %, 14 to 17 at %, or 15 to 17 at % in the alloy, the C element may be included at 0.5 to 2 at %, and thus it may be easy to control particle sizes of the grains generated through heat treatment, may improve reproducibility in mass production, and may be more advantageous for achieving increased permeability and decreased core loss. Moreover, according to the contents of the B and C elements, it may be advantageous that the Fe-based soft magnetic alloy has excellent magnetic properties, particularly, excellent permeability at high frequency in various forms, for example, a magnetic core, a ribbon sheet, and a flake-treated ribbon sheet.

Next, in the empirical formula, Cu is an element serving as a nucleation site that can generate α-Fe crystals in the initial alloy, making the amorphous initial alloy easily implemented as a nanograin alloy. The Cu element makes a crystal phase of the initial alloy amorphous, and makes the crystals generated after heat treatment become nanograins, and for the dramatic exhibition of desired physical properties, the Cu element is preferably included in the alloy at 0.5 to 1.2 at %, and more preferably 0.7 to 1.2 at %. When the Cu element is included in the alloy at less than 0.5 at %, the specific resistance of the manufactured alloy is greatly reduced, so the magnetic loss caused by an eddy current may increase, α-Fe nanograins are not generated in the heat-treated alloy to a desired level, and when the crystals are generated, it may not be easy to control the particle size of the generated crystals. In addition, when the Cu element is included in the alloy at more than 1.2 at %, the crystal phase of the manufactured initial alloy may be crystalline, the crystals previously generated in the initial alloy make the particle size of the crystals generated in heat treatment non-uniform, and crystals grown to more than a desired level of size may be included in the alloy, so the desired level of magnetic properties such as an increased magnetic loss may not be exhibited. In addition, as the contents of the above-described Fe, B and C elements and Nb to be described below are relatively decreased, the effect caused by the corresponding elements may be reduced.

Next, in the empirical formula, Nb is an element capable of improving the soft magnetic properties by increasing the uniformity of grain sizes in the alloy after heat treatment and reducing magnetostriction and magnetic anisotropy to contribute to the improvement in magnetic properties against a temperature change. Nb may be included at 0.8 to 3.0 at % in the alloy. When Nb may be included at less than 0.8 at %, the saturation magnetic flux density may slightly increase, but the decrease in particle size of nanograins upon heat treatment is insignificant, and it may be difficult to control a particle size and thus difficult to achieve excellent core loss and permeability. In addition, when Nb is more than 3.0 at %, there is a risk of increasing production costs, reducing the saturation magnetic flux density, increasing the coercive force, and it is difficult to implement an amorphous phase in the initial alloy. In addition, since amorphous implementation in the initial alloy is difficult, it may not be easy to control a particle size through heat treatment, there is a risk of reducing reproducibility in mass production, and there is a risk that coarse grains may be included in the alloy after heat treatment. In addition, it may be difficult to achieve desired levels, such as a great increase in the real part of permeability and/or an insignificant decrease in an imaginary part, when a ribbon sheet is implemented with the above-mentioned composition and/or a ribbon sheet is manufactured and then subjected to flake treatment.

Meanwhile, the composition of the Fe-based soft magnetic alloy according to the present invention does not include an Si element included in a conventional Fe-based soft magnetic alloy. While the Si element is known to increase the amorphous forming ability of the Fe-based alloy and reduce magnetostriction, when Si is included, it is not easy to form the crystal phase of the initial alloy in an amorphous phase. In addition, when Si is included in the alloy, there is a problem of reducing the contents of metalloids other than Fe, for example, B, C, Cu and Nb, or reducing the content of Fe, and the decrease in Fe content make it difficult to implement a Fe-based alloy with high saturation magnetic flux density. Moreover, there is a risk that the reproducibility of desired physical properties may not be ensured in mass production.

In addition, the present invention does not include a P element as an element constituting the alloy. The P element is known to help to implement a microstructure. To exhibit such a function, the P element must be included in the alloy at 3 at % or more and thus is not effective in implementing the microstructure, compared to Nb, and there is a problem of relatively reducing the content of another element. In addition, the P element has a low melting point, so it is not easy to manufacture an alloy, and it may be volatilized in ribbon manufacturing. Due to the above reasons, the P element make it difficult to amorphize the initial alloy, makes it difficult to control a grain size through the heat treatment of the initial alloy, and shows low permeability in a high frequency region, making it difficult to achieve high permeability. Particularly, in a flake process performed after heat treatment to reduce the magnetic loss caused by an eddy current, compared to the Fe-based alloy of the present invention, which does not include P, as pulverization is excessively performed, permeability may greatly decrease, and it may not be easy to control the permeability.

As such, elements not used in the present invention, which are known to implement a Fe-based soft magnetic alloy, have a problem in that it is difficult to exhibit magnetic properties to be implemented in the present invention. Therefore, even when several elements are able to be used to exhibit a certain function, if the element combination of the alloy according to the present invention and the ranges of the contents of these elements are not satisfied, it may be difficult to achieve all of desired physical properties in the present invention.

Therefore, in the empirical formula, a, b, c, d and e may satisfy 78.0≤a≤84.5, 12.55b≤17.0, 0.5≤c≤2, 0.5≤d≤1.2 and 0.8≤e≤3.0. In addition, a, b, c, d and e preferably satisfy 78.0≤a≤83.0, 13.0≤b≤17.0, 0.5≤c≤2, 0.5≤d≤1.2 and 0.8≤e≤3.0, more preferably 79.0≤a≤82.0, 14.0≤b≤17.0, 0.5≤c≤2, 0.5≤d≤1.2 and 0.8≤e≤3.0, and still more preferably 79.5≤a≤82.0, 15.0≤b≤17.0, 0.5≤c≤2, 0.5≤d≤1.2 and 0.8≤e≤1.5. Thus, production costs may be lowered, the Fe-based soft magnetic alloy may have excellent permeability in various forms such as a core, a ribbon sheet, and a flake-treated ribbon sheet, and a low magnetic loss may be ensured. In addition, it is easy to mass-produce the Fe-based soft magnetic alloy through first/second heat treatment processes to be described, and more improved magnetic properties may be achieved. In addition, the Fe-based soft magnetic alloy may be advantageous for exhibiting excellent magnetic properties, particularly excellent permeability at high frequency in various forms, for example, a magnetic core, a ribbon sheet, and a flake-treated ribbon sheet.

However, according to another embodiment of the present invention, to achieve excellent permeability, a high saturation magnetic flux density, and a low magnetic loss, for example, a decrease in core loss and coercive force, in the empirical formula, a, b, c, d and e may satisfy 79.5≤a≤82 and 18≤b+c+d+e≤20.5.

In addition, as, in the empirical formula, the sum of the Fe and Nb contents may be 78.8 to 85.5 at %, preferably 79.8 to 84.0 at %, and more preferably 81.0 to 83.0 at %, high saturation magnetic flux density and high permeability at high frequency may be achieved, and it may be easy to implement grains advantageous for controlling a crystal phase in the alloy and having a uniform particle size after initial alloying and heat treatment. When the sum of the Fe and Nb contents is less than 78.8 at % or more than 86 at %, the permeability may be significantly reduced at high frequency, for example, 100 kHz or 128 kHz, and/or the saturation magnetic flux density may be considerably reduced. In addition, it may be difficult to control grains, and coarse grains may be generated or grains may become non-uniform.

In addition, for example, as the value of Mathematical Formula 1 below with respect to a, b and e in the empirical formula may be 4.7 to 6.0, preferably 4.7 to 5.8, more preferably 4.7 to 5.5, still more preferably 4.7 to 5.3, and even more preferably 4.8 to 5.2, high saturation magnetic flux density and high permeability at high frequency may be achieved, and it may be easy to implement grains advantageous for controlling a crystal phase in the alloy and having a uniform particle size after initial alloying and heat treatment. When the value of the following Mathematical Formula 1 is less than 4.70, the saturation magnetic flux density may be significantly reduced, or both the saturation magnetic flux density and the permeability at high frequency may be significantly reduced. In addition, when the value of the following Mathematical Formula 1 is more than 5.60, the permeability at high frequency may be significantly reduced, and/or the saturation magnetic flux density may be significantly reduced. In addition, it may be difficult to control grains, and coarse grains may be generated or grains may become non-uniform.

$$\frac{a + e}{b} . \qquad [ Mathematical Formula 1 ]$$

In the Fe-based soft magnetic initial alloy according to one embodiment of the present invention having the above-described composition, a crystal phase may be substantially amorphous, and therefore, after heat treatment, the generation of coarse grains is prevented, and it is advantageous for uniformly forming the particle size of the generated grains. Here, the substantially amorphous means not only completely amorphous, a crystalline phase, which is completely amorphous, but also having some ultra-fine crystals with particle sizes of less than 1 nm, which are difficult to measure with the current technical level.

Meanwhile, the Fe-based soft magnetic alloy according to the present invention may be an alloy having the empirical formula FeₐB_{b}Cu_{d}Nbₑ, and may further contain unavoidable impurities that are unintentionally included in the manufacturing process. In one example, the impurity content may be 1 at % or less.

The Fe-based soft magnetic alloy heat-treated according to one embodiment of the present invention having the above-described composition may be manufactured by a manufacturing method to be described below, but the present invention is not limited thereto.

Specifically, the method of manufacturing the Fe-based soft magnetic alloy may include preparing a Fe-based initial alloy represented by the empirical formula FeₐB_{b}C_{c}Cu_{d}Nbₑ (wherein a, b, c, d and e are at % of corresponding elements and satisfy 78.0≤a≤84.5 and 15.5≤b+c+d+e≤22.0), and heat-treating the Fe-based initial alloy.

First, the step of preparing an initial alloy will be described. The Fe-based initial alloy included in one embodiment of the present invention may be prepared by melting a Fe-based alloy-forming composition in which base materials including elements are weighed and mixed to satisfy the empirical formula of the above-described Fe-based alloy or a Fe-based master alloy, and then solidifying the resulting product through rapid cooling. According to a specific method used in the solidification by rapid cooling, the shape of the manufactured Fe-based initial alloy may be changed. The method used in the solidification by rapid cooling may employ a conventionally known method, and the present invention is not particularly limited thereto. However, as a non-limiting example thereof, the solidification by rapid cooling may be performed by gas atomization for preparing a molten Fe-based master alloy or Fe-based alloy-forming composition in a powder phase with sprayed high-pressure gas (Ex. Ar, N₂, He, etc.) and/or high-pressure water, centrifugation for preparing a molten metal in a powder phase using a rapidly rotating disk, and melt spinning for preparing a ribbon by a roll rotating at a fast speed. The shape of the Fe-based soft magnetic initial alloy formed by such a method may be a magnetic core formed in a powder, a ribbon, or by winding the ribbon multiple times such that the core has a predetermined inner diameter and a predetermined outer diameter.

Meanwhile, the form of the Fe-based initial alloy may be bulk. When the form of the Fe-based initial alloy is bulk, powders of the amorphous Fe-based alloys formed by the above-described methods may be prepared into a bulk amorphous alloy by a conventionally known method, for example, consolidation and coagulation. As non-limiting examples of the consolidation, shock consolidation, explosive forming, sintering, hot extrusion and hot rolling may be used. Among these methods, in the shock consolidation, by applying a shock wave to the powdery alloy polymer, a wave propagates along the grain boundary and energy absorption occurs at the interface between grains, and the absorbed energy at this time may form a fine melting layer on a grain surface, thereby producing a bulk amorphous alloy. The formed melting layer must be cooled sufficiently rapidly to maintain an amorphous state through heat transfer into the grain. Through this method, a bulk amorphous alloy having a packing density of up to 99% of the original density of the amorphous alloy may be manufactured, and there is an advantage in that sufficient mechanical properties may be obtained. In addition, the hot extrusion and hot rolling utilizes the fluidity of an amorphous alloy at high temperature, and a bulk amorphous alloy having sufficient density and strength may be manufactured by heating an amorphous alloy powder to a temperature near Tg, rolling the heated product, and quenching it after rolling. On the other hand, the coagulation may include copper alloy mold casting, high pressure die casting, are melting, unidirectional melting, squeeze casting and strip casting, and each method may employ known method and conditions, and thus the present invention is not particularly limited thereto. In one example, the copper alloy mold casting is a method utilizing a suction method for injecting a molten metal into a copper mold having high cooling capacity using a pressure difference between the inside and outside of the mold or a compression method for injecting a molten metal by applying a uniform pressure from the outside, thereby manufacturing an amorphous Fe-based initial alloy having a certain bulk shape by metal coagulation of the molten metal injected into the copper mold at a high speed by compression or suction.

Afterward, the Fe-based soft magnetic initial alloy manufactured through the above-described method may be heat-treated to have appropriate magnetic properties.

The heat treatment is a step of transforming the atomic arrangement of the Fe-based initial alloy from amorphous to crystalline, and nanograins including α-Fe may be generated by the heat treatment. However, as the size and shape of crystals generated may vary depending on a temperature-increase rate and/or treatment time for heat treatment, the control of heat treatment conditions is very important in controlling grain size, content and shape.

Specifically, the heat treatment is preferably performed at a temperature equal to or less than 60° C. higher than the crystallization initiation temperature (Tx1) of the Fe-based initial alloy, for example, a heat treatment temperature of 430 to 530° C., more preferably, at heat treatment temperature of 430 to 510° C. within 30 minutes, more preferably, 15 minutes. Here, the heat treatment temperature may be controlled according to the composition, and the time condition may be suitable controlled according to the composition, a heat treatment temperature, and a temperature-increase rate. When the heat treatment temperature is less than 430° C., nanograins may not be generated or less generated, and in this case, a Fe-based soft magnetic alloy, which does not exhibit a desired magnetic property, may be manufactured. In addition, when the heat treatment temperature is more than 530° C., the particle size of the crystals generated in the alloy may be larger, the particle size distribution of the generated crystals is very wide, lowering the uniformity of the particle size, and crystals of a compound of Fe other than α-Fe and a different metal are excessively generated, so a Fe-based alloy, which is the uniform nanocrystalline of α-Fe, may not be obtained. In addition, due to the high heat temperature, the heat treatment time may be relatively shorter, making it more difficult to control the generated grains. Further, the implemented Fe-based soft magnetic alloy may not have a desired magnetic property.

In addition, according to one embodiment of the present invention, the temperature-increase rate to the heat treatment temperature may also affect the control of the particle size of the generated nanograins, and in one example, when a temperature-increase rate to the heat treatment temperature from room temperature is at most 100° C./min, it may be advantageous for generating a Fe-based soft magnetic alloy having a desired magnetic property.

However, even when the microstructure of the surface of the heat-treated alloy is implemented to have desired particle size distribution, it may be difficult to control the particle size distribution of grains distributed from the surface of the alloy in the depth direction, so there is a problem in that a soft magnetic alloy with a large magnetic loss is easily implemented. In addition, even when the same heat treatment method is applied to alloys of the same composition, the size of a grain in the alloy, the volume fraction, distribution, and the physical properties of the alloy after heat treatment are not uniform, making it difficult to mass produce.

Accordingly, the heat treatment according to the present invention includes first heat treatment and second heat treatment, which are performed at different temperatures, and thus a Fe-based soft magnetic alloy with uniform physical properties may be mass-produced, the volume fraction of nanograins is increased, size and distribution are easily controlled, and it is very suitable for manufacturing a Fe-based soft magnetic alloy in which microstructures present on the surface and in the alloy from the surface in the depth direction become more uniform, and a magnetic loss is significantly reduced. Further, in the first and second heat treatments performed on the composition of the preferable Fe-based soft magnetic alloy according to the present invention, there is an advantage of implementing a Fe-based soft magnetic alloy exhibiting more improved permeability and reduced core loss, compared to a soft magnetic alloy undergoing a conventional heat treatment process.

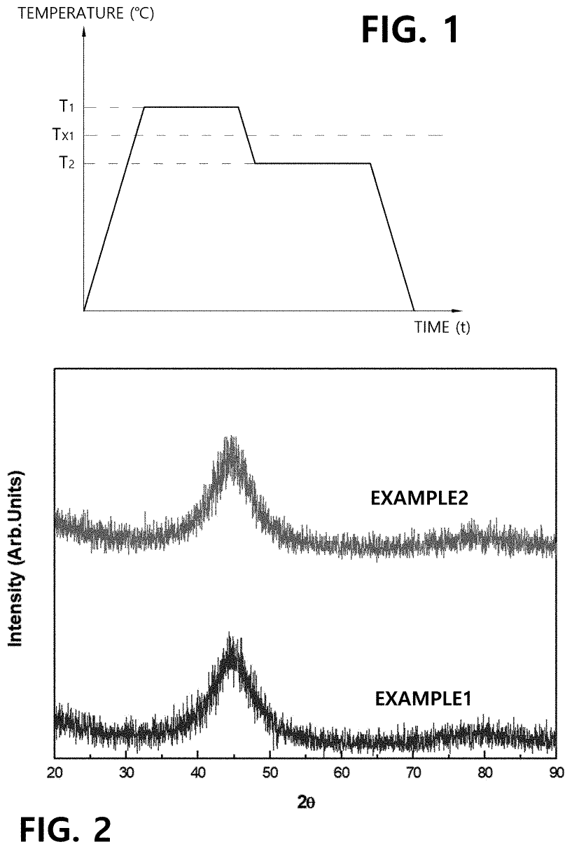

Referring to FIG. 1, the first heat treatment is performed at a first heat treatment temperature (T₁) higher than the crystallization initiation temperature (Tx₁) of the Fe-based initial alloy, and then the second heat treatment is performed at a second heat treatment temperature (T₂) lower than the first heat treatment temperature (T₁). If the second heat treatment temperature (T₂) is higher than the first heat treatment temperature (T₁), permeability may be even degraded, and there are risks of decreasing a maximum magnetic flux density, and increases in a coercive force and core loss. In addition, it may be difficult to achieve improved reproducibility.

The first heat treatment may be performed at the first heat treatment temperature (T₁) for a predetermined time. Preferably, the temperature-increase rate to the first heat treatment temperature (T₁) is 100° C./min or less, and more preferably, 10 to 100° C./min. When the temperature-increase rate is less than 10° C., when the temperature is raised, a heat treatment effect may occur, and it may be difficult to express a magnetic property and control a microstructure, and when the temperature-increase rate is more than 100° C., equipment satisfying the temperature-increase rate may be limited, difficult to construct, and may not be suitable for mass production.

The first heat treatment temperature (T₁) is performed at a higher temperature than the crystallization initiation temperature (Tx₁) in a DSC curve for the initial alloy manufactured in Step 1, and is preferably more than Tx₁ to (Tx₁+60) ° C. When the first heat treatment is performed at Tx₁° C. or less, the heat treatment time may be extended, and the extended heat treatment time may make it difficult to control the microstructure. In addition, it may be difficult to exhibit a desired level of permeability. In addition, when the first heat treatment is performed at a temperature more than (Tx₁+60) ° C., the temperature is set high, and thus the heat treatment time has to be shortened, and due to the short heat treatment time, it may not be easy to obtain uniform characteristics and a uniform microstructure, so it may be undesirable for reproducibility in mass production. In addition, in a flake process which is added after heat treatment, excessive pulverization of the alloy may occur, and permeability may be significantly reduced.

In addition, the first heat treatment may be performed at the above-described first heat treatment temperature (T₁) for 2 to 30 minutes, and more preferably, 5 to 25 minutes, and the specific time may be controlled by the selected first temperature. When the maintenance at the first temperature is less than 2 minutes, although the first temperature is selected from a relatively high temperature range, it may be difficult to generate crystals sufficiently at a desired level or to exhibit a desired level of magnetic properties, and when the first temperature is selected from a higher range, as it is difficult to control crystal growth and physical properties, reproducibility may be significantly reduced. In addition, when the maintenance at the first temperature exceeds 30 minutes, there is a risk of extending production time, and even when the first temperature is selected to be low, the desired level of magnetic properties is not exhibited, and when the first temperature is selected to be high, excessive heat treatment may cause coarsening of a crystalline phase. Thus, as iron loss significantly increases or becomes too large, it may be impossible to measure the iron loss using a measuring device, and permeability may be significantly reduced or become too small to measure using the measuring device. After the above-described first heat treatment, at the second heat treatment temperature (T₂), second heat treatment is performed, and the second heat treatment temperature (T₂) is lower than the crystallization initiation temperature (Tx₁) of the initial alloy, and when the second heat treatment temperature is higher than the first heat treatment temperature, it is difficult for the present invention to achieve the desired effect. The first heat treatment temperature and the second heat treatment temperature are preferably designed to have a difference of 60° C. or less, more preferably 50° C. or less, still more preferably 15 to 50° C., and even more preferably 25 to 35° C. When the temperature difference is more than 60° C., since a proper grain size or distribution is not formed, the maximum magnetic flux density may be low, and permeability improvement may be insignificant or permeability may even be reduced. In addition, there is a risk of exhibiting a high coercive force and high core loss. Moreover, there is a risk of significantly degrading reproducibility. In addition, when the second temperature is set to have a temperature difference of less than 20° C., there is a risk of degrading reproducibility.

Here, the cooling rate from the first heat treatment temperature (T₁) to the second heat treatment temperature (T₂), which are described above, is preferably 100° C./min or less, and more preferably 10 to 100° C./min, and when the cooling rate is less than 10° C./min, due to the heat treatment effect during cooling, it may be difficult to control a microstructure. In addition, when the cooling rate is more than 100° C./min, the increase in effect may be insignificant, and production costs may increase.

The second heat treatment temperature (T₂) is preferably a temperature of (Tx₁−55)° C. to (Tx₁+20)° C. When the second heat treatment is performed below (Tx₁−55)° C., the heat treatment time is extended, which is not good for mass production, and there may be difficulty in implementing characteristics, for example, low permeability due to poor grain growth, and an alloy having a high magnetic loss. In addition, when the second heat treatment is performed at a temperature more than (Tx₁+20) ° C., coarse grain growth may occur, thereby degrading magnetic properties such as an increase in core loss or coercive force, and a soft magnetic alloy having a large variation in physical properties may be manufactured, so it cannot be preferable in terms of reproducibility.

In addition, the second heat treatment may be performed at the above-described second heat treatment temperature (T₂) for 5 to 70 minutes, and more preferably 10 to 60 minutes, and the specific time may be controlled by the selected second heat treatment temperature. However, when the heat treatment is performed over a proper level of the heat treatment time at the selected second heat treatment temperature, a significant decrease in permeability and a significant increase in coercive force may be induced. Specifically, when the heat treatment is performed for less than 5 minutes, due to short heat treatment, a uniform microstructure may not be obtained, making it difficult to exhibit magnetic properties. In addition, when the heat treatment is performed over 70 minutes, abnormal grain growth may occur, resulting in degradation in physical properties such as a significant decrease in the real part of the complex permeability or a significant increase in the imaginary part.

On the other hand, after the second heat treatment at the second heat treatment temperature, the cooling rate to room temperature may be 30 to 300° C./min, which may be advantageous for achieving the purpose of the present invention.

In the present invention, a two-step heat treatment process including first heat treatment performed at a higher temperature than the crystallization initiation temperature (Tx₁) of the initial alloy and then second heat treatment performed at a lower temperature than that of the first heat treatment may be performed, and when any one of these steps is omitted or the heat treatment order is changed so that the heat treatment is performed first under the second heat treatment condition and then under the first heat treatment, it may be difficult to implement a desired microstructure, and reduce the magnetic loss to a desired level.

However, Step 2 may be performed by adding pressure and/or magnetic field other than heat. Through the additional treatment, crystals having magnetic anisotropy in a specific direction may be generated. As the level of the applied pressure or magnetic field may be changed depending on the degree of the desired physical properties, the present invention is not limited thereto, and may be performed under known conditions.

Through the above-described method, a soft magnetic alloy manufactured by heat treatment of the Fe-based initial alloy may have an amorphous structure, or may include a grain having an average particle size of 60 nm or less, preferably 50 nm or less, more preferably 40 nm or less, still more preferably 35 nm or less, even more preferably 25 nm or less, and yet more preferably 20 nm or less in the amorphous matrix. When the average particle size of the grain is more than 60 nm, it may not be possible to satisfy all of the desired magnetic properties, such as an increase in coercive force and a decrease in permeability. However, when the proportion of grains having a particle diameter of less than 15 nm is high among the grains, it may not be easy to achieve high permeability.

In addition, when the soft magnetic alloy includes grains, the grains may be included at 50 vol % or more, preferably 50 to 70 vol %, and more preferably 60 to 70 vol %. When grains are included at less than 50 vol %, it may not exhibit desired magnetic properties such as a desired level of saturation magnetic flux density. In addition, when grains are included at more than 70 vol %, the generation of crystals of a compound other than an α-Fe crystal among the generated crystals may be increased, and desired magnetic properties may not be exhibited. In addition, when grains are included more than 70 vol %, it may be difficult for the particle size of the grains to be uniform, and even when the grains are uniformly implemented, the improvement in physical properties may be insignificant.

In addition, among grains distributed from the surface to a depth of 5 μm through the above-described heat treatment of the present invention, coarse grains having a particle size of more than 80 nm may not be included in the soft magnetic alloy. When grains having an average particle size of 60 nm or less and a particle size of more than 80 nm are included, the particle size of the grain may have a non-uniform microstructure, and thus there is a risk of degrading permeability according to an increase in magnetic anisotropy, and it may be difficult to reduce magnetic loss. Among grains distributed from the surface to a depth of 5 μm, coarse grains preferably having a particle size of 60 nm, and more preferably more than 40 nm, may not be included in the soft magnetic alloy.

In addition, in the Fe-based soft magnetic alloy, the average particle size is 60 nm or less, and the particle sizes of grains may be very uniform. Particularly, the particle sizes of the grains located on the surface are uniform, and the grains distributed from the surface of the alloy in a depth direction may have uniform particle sizes, thereby implementing a very low coercive force and core loss. Therefore, compared to a conventional Fe-based soft magnetic alloy having the same composition, significantly low magnetic loss may be achieved. In the Fe-based soft magnetic alloy, among grains distributed from the surface to a depth of 5 μm, grains having a particle diameter of ±20% with respect to the predetermined average particle size of the grains are included at preferably 50% or more, more preferably 65% or more, still more preferably 70% or more, and even more preferably 80% or more of the total grains, so it may be suitable to express a significantly low magnetic loss to a desired level. When grains having a particle diameter deviating from ±20% with respect to the predetermined average particle size is less than 50% of the total grains, a microstructure having a non-uniform particle size distribution of the grains included in the soft magnetic alloy may be implemented, and thus it may be difficult to reduce magnetic loss to a desired level.

In addition, the difference in average particle sizes between a group of first grains distributed from the surface to a depth of 2.5 μm and a group of second grains distributed from a depth of 2.5 to a depth of 5.0 μm from the surface is preferably 10 nm or less, more preferably 5 nm or less, and still more preferably 2 nm or less, and through this, the particle size distribution of the grains distributed from the surface of the Fe-based soft magnetic alloy in a depth direction is very uniform, which is suitable for exhibiting a significantly low magnetic loss to a desired level.

The manufactured Fe-based soft magnetic alloy may be formed in a ribbon sheet having predetermined thickness and width, or a magnetic core having predetermined outer and inner diameters by winding the ribbon multiple times. When the Fe-based soft magnetic alloy is formed in a magnetic core, a saturation magnetic flux density is 1.5 T or more, a coercive force is 10.0 A/m or less, and a core loss at IT and 50 Hz is 150 mW/kg or less, under conditions of 800 A/m and a magnetic field of 50 Hz. In addition, the maximum magnetic flux density measured under the same conditions may be 1.45 T or more. Here, the magnetic core may be prepared by winding a ribbon sheet with a thickness of approximately 20 μm and a width of 20 mm to have an outer diameter of 20 nm and an inner diameter of 10 nm.

In addition, when the outer diameter is 20 nm and the inner diameter is 10 mm at a frequency of 100 kHz, the permeability of the magnetic core may be 3000 or more, preferably 3500 or more, more preferably 4800 or more, still more preferably 5500 or more, even more preferably 6000 or more, and further more preferably 6500 or more.

In addition, the Fe-based soft magnetic alloy according to one embodiment of the present invention may be implemented in magnetic parts of electrical and electronic devices.

In one example, the Fe-based soft magnetic alloy may be implemented as an electromagnetic shielding material. Here, the soft magnetic alloy may be a ribbon sheet, and one or multiple layers of the ribbon sheet may be laminated. The electromagnetic shielding material may further include protective members which cover the top and bottom of the single- or multi-layer-laminated ribbon sheet, and the protective member may be a known member used in the electromagnetic shielding material, and the present invention is not particularly limited thereto.

Meanwhile, the ribbon sheet-formed Fe-based soft magnetic alloy included in the electromagnetic shielding material may be included in an electromagnetic shielding material formed by laminating a ribbon sheet broken into multiple pieces in a single or multiple layers through flake treatment for improving the magnetic loss according to an eddy current.

However, since the ribbon sheet is in a divided state, in consideration of this, it is preferably divided into a suitable size, a suitable spacing, and a suitable shape. When the ribbon sheet is divided into excessively small pieces, permeability may be significantly reduced, and when the ribbon sheet is divided into excessively large pieces, the decrease in magnetic loss may be insignificant.

In the above-described electromagnetic shielding material according to one embodiment of the present invention formed through flake treatment of the ribbon sheet, a real part (μ′) of the complex permeability at a frequency of 100 kHz may be 1000 or more, preferably 1200 or more, more preferably 1300 or more, and still more preferably 1400 or more, and an imaginary part (μ″) thereof may be 200 or less. In addition, the Fe-based soft magnetic alloy may be implemented as a coil part. Here, the soft magnetic alloy may be in the form of a magnetic core, and a coil may be wound around the magnetic core. The coil part may be applied to a part of a laser, a transformer, an inductor, a motor or a generator.

### EXAMPLES

The present invention will be described in more detail through the following examples, but the following examples are not intended to limit the scope of the present invention, which should be construed to help understanding of the present invention.

### Example 1

A Fe master alloy was manufactured using an are melting method after measurement of raw materials of Fe, B, C, Nb and Cu to manufacture a Fe master alloy represented by the empirical formula Fe_{80.3}B_{16.8}C_{1.0}Cu_{0.9}Nb_{1.0}. Afterward, a ribbon-shaped Fe-based soft magnetic initial alloy having a thickness of approximately 20 μm and a width of approximately 20 mm was manufactured by melting the manufactured Fe master alloy and performing rapid cooling at 10⁶ K/sec through melt spinning in an Ar atmosphere at 60 m/s.

Afterward, Fe-based soft magnetic alloys shown in Table 1 below were manufactured by winding the manufactured ribbon-shaped Fe-based soft magnetic initial alloy to have an outer diameter of 20 mm and an inner diameter of 10 mm and heat-treating the magnetic core-shaped initial alloy or ribbon-shaped initial alloy at room temperature and a temperature-increase rate of 80° C./min.

### Examples 2 to 16

Fe-based soft magnetic alloys shown in Table 2 or 3 below were manufactured in the same manner as described in Example 1, except that a composition and/or a heat treatment temperature and time were changed as shown in Table 2 or 3 below.

### Comparative Examples 1 to 5

Fe-based soft magnetic alloys shown in Table 3 were manufactured in the same manner as described in Example 1, except that a composition and/or a heat treatment temperature and time were changed as shown in Table 3 below.

### Experimental Example 1

The following physical properties of the initial alloys and the heat-treated alloys manufactured in Examples 1 to 16 and Comparative Examples 1 to 5 were evaluated, and the results are shown in Tables 1 to 3 below.

1. Analysis of Crystal Structure

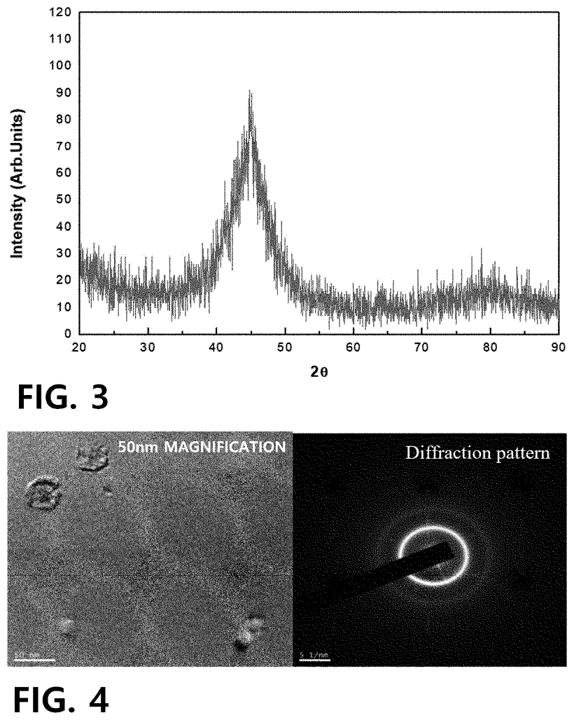

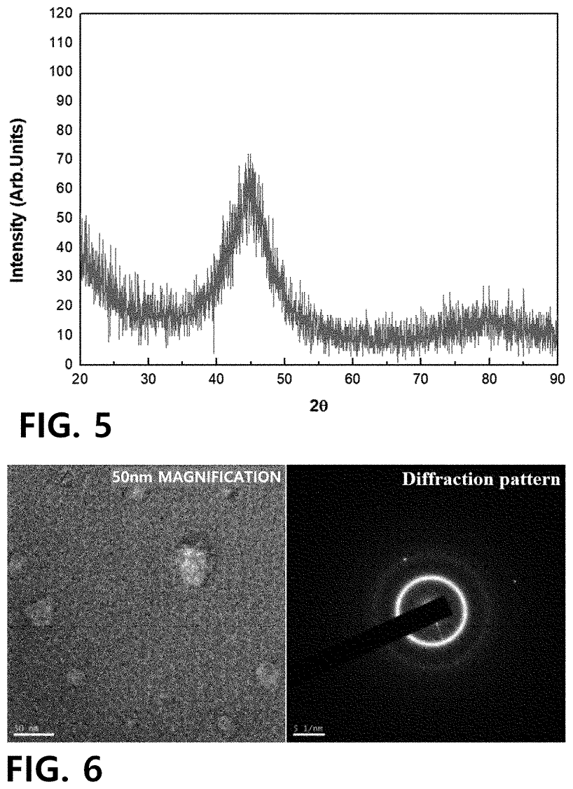

XRD patterns and TEM images were analyzed to confirm the crystal phases of the manufactured initial alloys and heat-treated alloys and the average particle size of the generated crystals. Here, among the analyzed results, the XRD patterns for the Fe-based soft magnetic alloys before heat treatment of Examples 1 and 2 are shown in FIG. 2. In addition, the XRD patterns and TEM images according to Example 1 after heat treatment are shown in FIGS. 3 and 4, and the XRD patterns and TEM images according to Example 2 are shown in FIGS. 5 and 6.

Here, the volume fraction of crystals was calculated by Mathematical Formula 1 below from the XRD pattern.

$$[ Mathematical Formula 1 ]$$

$$vol \% = [ area of crystalline region / ( area of crystalline region + area of amorphous region ) ] \times 100$$

In addition, the average particle size was obtained from the Scherrer formula as shown in Mathematical Formula 2 below.

$$D = \frac{0.9 λ}{β cos θ} \qquad [ Mathematical Formula 2 ]$$

Here, D is the average particle size of a crystal, β is the half width of the peak with the maximum intensity, and β is the angle at which a peak has the maximum intensity.

2. Evaluation of Magnetic Properties

The coercive force and saturation magnetization value (Bs) or the maximum magnetic flux density (Bm) of Sample 1, which is a magnetic core, were assessed using a vibrating sample magnetometer (VSM) at 800 A/m and 50 Hz. In addition, Pcm was assessed using a measuring device, such as a BH tracer (Iwatsu, SY-8219), at IT and 50 Hz. In addition, permeability was measured using an LCR meter after a toroidal magnetic core was inserted into a plastic bobbin of the same size and wound twenty turns with a copper wire coated with an insulation material. Here, the measurement was performed under conditions including a frequency of 100 kHz and IV.

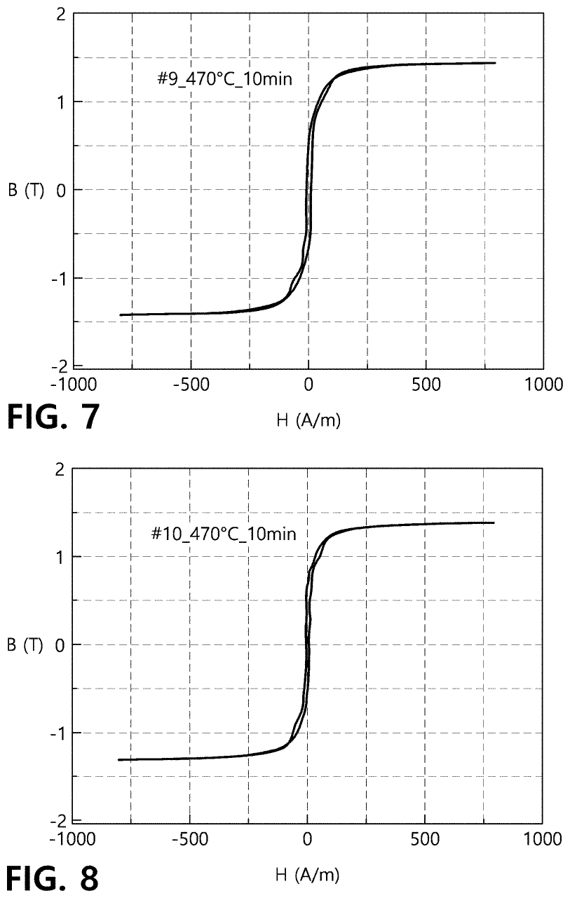

Among the results, the VSM graphs of the Fe-based soft magnetic alloys of Examples 1 and 2 are shown in FIGS. 7 and 8, respectively.

In addition, for Sample 2 derived from a ribbon sheet, the real part and imaginary part of permeability at a frequency of 100 kHz were measured using a dedicated fixture (KEYSIGHT42942A, 16454A) shown in FIG. 12.

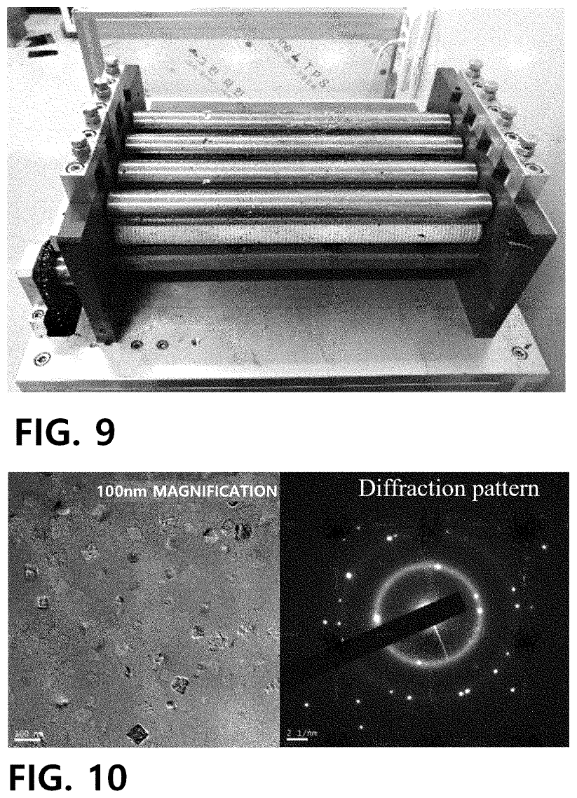

Here, Sample 2 was prepared in a toroidal form with an outer diameter of 20 mm and an inner diameter of 10 mm, after protective films were attached to the top and bottom of the ribbon sheet and then passed through a flake device shown in FIG. 9 three times.

TABLE 1

| | | Example 1 | Example 2 | Example 3 | Example 4 | Example 5 | Example 6 | Example 7 |
|---|---|---|---|---|---|---|---|---|
| Alloy | Fe | 80.3 | 79.8 | 81 | 81 | 81.3 | 82 | 83 |
| | B | 16.8 | 16.8 | 16.1 | 15.6 | 15.3 | 14.6 | 14 |
| | C | 0.9 | 0.9 | 0.9 | 0.9 | 0.9 | 0.9 | 1 |
| | Cu | 1 | 1 | 1 | 1 | 1 | 1 | 1 |
| | Nb | 1 | 1.5 | 1 | 1.5 | 1.5 | 1.5 | 1 |
| | Si or P | 0 | 0 | 0 | 0 | 0 | 0 | 0 |
| | Mathematical | 4.84 | 4.84 | 5.09 | 5.29 | 5.41 | 5.72 | 6.00 |
| | Formula 1 | | | | | | | |
| Heat treatment | | 470/10 | 450/10 | 440/10 | 430/10 | 430/10 | 420/10 | 420/10 |
| temperature/time (° C./min.) | | | | | | | | |
| Structure | before heat | amorphous | amorphous | amorphous | amorphous | amorphous + | amorphous | amorphous |
| | treatment | | | | | crystalline | | |
| | after heat treatment | crystalline | crystalline | crystalline | crystalline | crystalline | crystalline | crystalline |
| | Average particle | <25 nm | <10 nm | <10 nm | <10 nm | <30 nm | <10 nm | <10 nm |
| | size | | | | | | | |
| | Presence of coarse | None | None | None | None | 43 | None | None |
| | grains in grains | | | | | | | |
| | distributed from | | | | | | | |
| | surface to a depth | | | | | | | |
| | of 5 μm and | | | | | | | |
| | maximum particle | | | | | | | |
| | size (nm) of coarse | | | | | | | |
| | grain | | | | | | | |
| Bs (T) | | 1.61 | 1.54 | 1.58 | 1.59 | 1.64 | 1.68 | 1.7 |
| Hc (A/m) | | 4.09 | 7.09 | 9.17 | 7.4 | 8.2 | 7.1 | 7.7 |
| Pcm (mW/kg) | | 109 | 87 | 94 | 122 | 140 | 130 | 150 |
| Core | Maximum | 6528 | 5995.3 | 5297.5 | 4985.1 | 3500 | 3450 | 3100 |
| | permeability | | | | | | | |
| | (@ 100 kHz) | | | | | | | |
| Flake- | μ’ (@ 100 kHz) | 1472.3 | 1345.9 | 1194.8 | 1233.3 | 1000.4 | 778.1 | 712.4 |
| treated | μ″ (@ 100 kHz) | 177.9 | 109.8 | 95.6 | 100.1 | 63.2 | 62.2 | 55.9 |
| magnetic | | | | | | | | |
| sheet | | | | | | | | |

TABLE 2

| | | Example 8 | Example 9 | Example 11 | Example 12 | Example 13 | Example 14 | Example 15 |
|---|---|---|---|---|---|---|---|---|
| Alloy | Fe | 83.3 | 83.3 | 84 | 79.8 | 79 | 78 | 80 |
| | B | 13.7 | 12.7 | 12 | 17.3 | 15.8 | 16.8 | 15 |
| | C | 1 | 1 | 1 | 0.9 | 2 | 2 | 1 |
| | Cu | 1 | 1 | 1 | 1 | 1 | 1 | 1 |
| | Nb | 1 | 2 | 2 | 1 | 2.2 | 2.2 | 3 |
| | Si or P | 0 | 0 | 0 | 0 | 0 | 0 | 0 |
| | Mathematical | 6.15 | 6.72 | 7.17 | 4.67 | 5.14 | 4.77 | 5.53 |
| | Formula 1 | | | | | | | |
| Heat treatment | | 410/10 | 410/10 | 400/10 | 450/10 | 450/10 | 480/10 | 450/10 |
| temperature/time (° C./min.) | | | | | | | | |
| Structure | before heat | amorphous + | amorphous + | crystalline | amorphous | amorphous | amorphous | amorphous |
| | treatment | crystalline | crystalline | dominant | | | | |
| | after heat treatment | crystalline | crystalline | crystalline | crystalline | crystalline | crystalline | crystalline |
| | Average particle | <30 nm | <30 nm | <50 nm | <30 nm | <20 nm | <20 nm | <20 nm |
| | size | | | | | | | |
| | Presence of coarse | 53 | 50 | 68 | None | None | None | None |
| | grains in grains | | | | | | | |
| | distributed from | | | | | | | |
| | surface to a depth | | | | | | | |
| | of 5 μm and | | | | | | | |
| | maximum particle | | | | | | | |
| | size (nm) of coarse | | | | | | | |
| | grain | | | | | | | |
| Bs (T) | | 1.76 | 1.77 | 1.79 | 1.53 | 1.55 | 1.5 | 1.6 |
| Hc (A/m) | | 7.6 | 6.8 | 6.6 | 7.3 | 6.5 | 6.4 | 6.3 |
| Pcm (mW/kg) | | 150 | 140 | 160 | 150 | 130 | 120 | 130 |
| Core | Maximum | 3050 | 3000 | 1900 | 6005.5 | 6304 | 6600 | 6015 |
| | permeability | | | | | | | |
| | (@ 100 kHz) | | | | | | | |
| Flake- | μ’ (@ 100 kHz) | 687.9 | 676.6 | 428.5 | 1349.8 | 1420.9 | 1488.5 | 1353.2 |
| treated | μ″ (@ 100 kHz) | 55.0 | 54.1 | 34.3 | 153.9 | 113.7 | 130.8 | 108.3 |
| magnetic | | | | | | | | |
| sheet | | | | | | | | |

TABLE 3

| | | Example | Comparative | Comparative | Comparative | Comparative | Comparative |
|---|---|---|---|---|---|---|---|
| | | 16 | Example 1 | Example 2 | Example 3 | Example 4 | Example 5 |
| Alloy | Fe | 80 | 84.3 | 85 | 77.5 | 83.3 | 83.3 |
| | B | 14.5 | 13.7 | 12 | 16.5 | 13.7 | 13.7 |
| | C | 1 | 1 | 1 | 2 | 1 | 1 |
| | Cu | 1 | 1 | 1 | 1 | 1 | 1 |
| | Nb | 3.5 | 0 | 1 | 2.2 | 1 | 1 |
| | Si or P | 0 | 0 | 0 | 0 | Si/2 | P/2 |
| | Mathematical | 5.76 | 6.15 | 7.17 | 4.83 | 6.15 | 6.15 |
| | Formula 1 | | | | | | |
| Heat treatment | | 450/10 | 400/10 | 390/10 | 490/10 | 420/10 | 420/20 |
| temperature/time (° C./min.) | | | | | | | |
| Structure | before heat | amorphous | amorphous + | crystalline | amorphous | amorphous + | amorphous + |
| | treatment | | crystalline | dominant | | crystalline | crystalline |
| | after heat treatment | crystalline | crystalline | crystalline | crystalline | crystalline | crystalline |
| | Average particle | <20 nm | <10 nm | <10 nm | <60 nm | <30 nm | <30 nm |
| | size | | | | | | |
| | Presence of coarse | None | None | None | 62 | 48 | None |
| | grains in grains | | | | | | |
| | distributed from | | | | | | |
| | surface to a depth | | | | | | |
| | of 5 μm and | | | | | | |
| | maximum particle | | | | | | |
| | size (nm) of coarse | | | | | | |
| | grain | | | | | | |
| Bs (T) | | 1.61 | 1.81 | 1.83 | 1.47 | 1.72 | 1.76 |
| Hc (A/m) | | 6.3 | 10.2 | 15.1 | 6.5 | 6.7 | 8.7 |
| Pcm (mW/kg) | | 130 | 240 | 430 | 70 | 130 | 130 |
| Core | Maximum | 6000 | 1300 | 900 | 1200 | 3327 | 1289.6 |
| | permeability | | | | | | |
| | (@ 100 kHz) | | | | | | |
| Flake- | μ’ (@ 100 kHz) | 1304.4 | 293.2 | 203.0 | 270.6 | 750.4 | 322.4 |
| treated | μ″ (@ 100 kHz) | 127.6 | 23.5 | 16.2 | 21.7 | 60.0 | 94.8 |
| magnetic | | | | | | | |
| sheet | | | | | | | |

As confirmed from Tables 1 to 3, as compared to the Fe-based soft magnetic alloys according to Comparative Examples, it can be seen that the Fe-based soft magnetic alloys according to Examples had excellent magnetic properties, and also exhibited excellent permeability even when implemented differently in a magnetic core or a flake-treated magnetic sheet.

### Examples 17 and 18

Fe-based soft magnetic alloys were manufactured in the same manner as described in Example 1, except that initial alloys were subjected to heat treatment at room temperature and a temperature-increase rate of 80° C./min, as shown in Table 4 below.

### Example 19

A Fe-based soft magnetic alloy shown in Table 4 below was manufactured in the same manner as described in Example 1, except that an initial alloy was subjected to heat treatment at room temperature and a temperature-increase rate of 80° C./min until 460° C., heat treatment again for 10 minutes, cooled at a cooling rate of 70° C./min to 445° C., subjected to heat treatment at a corresponding temperature for 15 minutes, and cooled at 250° C./min to room temperature, that is, 25° C.

### Examples 20 to 24

Fe-based soft magnetic alloys were manufactured in the same manner as described in Example 19, except that initial alloys were subjected to heat treatment and changes as shown in Table 4 or 5 below.

### Experimental Example 2

A total of 100 magnetic cores per Examples, which are Specimens 1, for the Fe-based soft magnetic alloys according to Examples 17 to 24 were manufactured and then their crystal structures and magnetic properties were measured in the same manner as described in Experimental Example 1. Here, the magnetic properties were represented by calculating the average value for the 100 specimens, and in the case of average permeability, the standard deviation was also calculated, and the results are shown in Table 4 or 5.

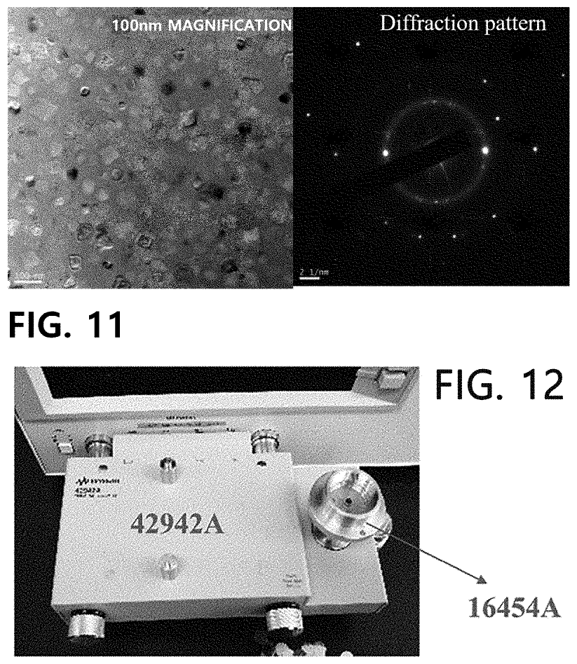

In addition, the TEM images for Examples 20 and 22 measured in crystal structure analysis are shown in FIGS. 10 and 11, respectively.

TABLE 4

| | Example | Example | Example | Example |
|---|---|---|---|---|
| | 17 | 18 | 19 | 20 |
| Tx1 (° C.) | 436 | 436 | 436 | 436 |
| First heat treatment temperature/time (min) | 460/10 | 510/7 | 460/10 | 460/10 |
| Second heat treatment temperature/time (min) | Not performed | Not performed | 445/15 | 430/25 |
| First heat treatment temperature-Second | — | — | 15 | 30 |
| heat treatment temperature | | | | |
| Structure after heat treatment | crystalline | crystalline | crystalline | crystalline |
| Average particle size | >25 nm | >5 nm | >20 nm | 20 nm |
| vol % of grains | 51 | 30 | 60 | 65 |
| Proportion of grains with particle size of ±20% of | 50 | 30 | 60 | 74 |
| predetermined average particle size among grains | | | | |
| distributed from surface to a depth of 5 μm (%) | | | | |
| Average permeability (@100 kHz) | 6,000.25 | 4,234.55 | 6,500.00 | 6,778.80 |
| Standard deviation of permeability | 350.67 | 891.87 | 210.23 | 97.84 |
| Average Bm (T) | 1.47 | 1.47 | 1.45 | 1.460 |
| Average Hc (A/m) | 5.04 | 5.81 | 4.70 | 4.31 |
| Average Pcm (mW/kg) | 140 | 131 | 120 | 111 |

TABLE 51

| | Example | Example | Example | Example |
|---|---|---|---|---|
| | 21 | 22 | 23 | 24 |
| Tx1 (° C.) | 436 | 436 | 436 | 436 |
| First heat treatment temperature/time (min) | 490/7 | 510/7 | 430/15 | 450/10 |
| Second heat treatment temperature/time (min) | 430/30 | 430/30 | 390/50 | 470/10 |
| First heat treatment temperature-Second | 60 | 80 | 40 | −20 |
| heat treatment temperature | | | | |
| Structure after heat treatment | crystalline | crystalline | crystalline | crystalline |
| Average particle size | 35 | 41 | 5 nm | 40 nm |
| vol% of grains | 72 | 76 | 10 | 63 |
| Proportion (%) of grains with particle size of ±20% of | 80 | 26 | 65 | 40 |
| predetermined average particle size among grains | | | | |
| distributed from surface to a depth of 5 μm | | | | |
| Average permeability (@100 kHz) | 5,514.70 | 4,357.20 | 4,100.00 | 4,605.40 |
| Standard deviation of permeability | 100.56 | 997.08 | 90.50 | 480.94 |
| Average Bm (T) | 1.460 | 1.420 | 1.420 | 1.43 |
| Average Hc (A/m) | 5.870 | 10.350 | 5.700 | 10.10 |
| Average Pcm (mW/kg) | 176.4 | 208.4 | 120.0 | 200.5 |

As confirmed from Tables 4 and 5, compared to Examples 17 and 18 in which one-step heat treatment was performed, in Examples 19 and 20 in which two-step heat treatment was performed, it can be confirmed that the standard deviation of permeability is small, and thus reproducibility is excellent.

In addition, in Example 24 exhibiting a higher second heat treatment temperature than the first heat treatment temperature in the two-step heat treatment, it can be seen that reproducibility is poor, and an improvement in permeability is insignificant.

Although exemplary embodiments of the present invention have been described above, the spirit of the present invention is not limited to the exemplary embodiments presented herein, and it will be understood by those of ordinary skill in the art that other exemplary embodiments may be easily suggested by adding, changing, deleting or adding components within the scope of the same idea and also included in the scope of the spirit of the present invention.

1. A Fe-based soft magnetic alloy manufactured through heat treatment of an initial alloy represented by the empirical formula FeₐB_{b}C_{c}Cu_{d}Nbₑ,
wherein, in the empirical formula, a, b, c, d and e are atomic percents (at %) of corresponding elements, respectively, and satisfy 78.0≤a≤84.5 and 15.5≤b+c+d+e≤22.0.

2. The alloy of claim 1, wherein, in the empirical formula, a, b, c, d and e satisfy 78.0≤a≤84.5, 12.5≤b≤17.0, 0.5≤c≤2, 0.5≤d≤1.2, and 0.8≤e≤3.0.

3. The alloy of claim 1, which has an amorphous structure or includes grains having an average particle size of 60 nm or less in an amorphous matrix.

4. The alloy of claim 2, wherein, in the empirical formula, a and b satisfy 79.0≤a≤82.0 and 14.0≤b≤17.0.

5. The alloy of claim 1, which has a saturation magnetic flux density of 1.5 T or more, a coercive force of 10.0 A/m or less, and a core loss of 150 mW/kg or less at 1 T and 50 Hz, under conditions of 800 A/m and a magnetic field of 50 Hz.

6. The alloy of claim 1, wherein the value of Mathematical Formula 1 below with respect to a, b and e in the empirical formula is in the range of 4.7 to 6.0:
$$\frac{a + e}{b} . \qquad [ Mathematical Formula 1 ]$$

7. The alloy of claim 1, wherein the average particle size of a crystal is 35 nm or less, and the volume fraction thereof is 50% or more.

8. The alloy of claim 1, which does not include a coarse grain having a particle size of more than 80 nm among grains distributed from the surface to a depth of 5 μm.

9. The alloy of claim 1, wherein, among the grains distributed from the surface to a depth of 5 μm, grains having a particle size of ±20% of the average particle size account for 50% or more of the total grains.

10. The alloy of claim 1, wherein a permeability of a magnetic core formed of the Fe-based soft magnetic alloy at 100 kHz is 3000 or more, and an imaginary part of the complex permeability of a flaked magnetic sheet is 1000 or more.

11. A method of manufacturing a Fe-based soft magnetic alloy, comprising:
preparing a Fe-based initial alloy represented by the empirical formula FeₐB_{b}C_{c}Cu_{d}Nbₑ (here, a, b, c, d and e are atomic percents (at %) of corresponding elements, respectively, and satisfy 78.0≤a≤84.5 and 15.5≤b+c+d+e≤22.0); and
heat-treating the Fe-based initial alloy.

12. The method of claim 11, wherein the heat treatment includes first heat treatment performed at a first heat treatment temperature higher than the crystallization initiation temperature (Tx₁) of the Fe-based initial alloy, and second heat treatment performed at a second heat treatment temperature lower than the first heat treatment temperature after the first heat treatment.

13. The method of claim 12, wherein the first heat treatment temperature is more than Tx₁° C. to (Tx₁+60) ° C., and the second heat treatment temperature is more than (Tx₁−55° C.) to (Tx₁+20° C.).

14. The method of claim 12, wherein the first heat treatment is performed for 2 to 30 minutes.

15. The method of claim 12, wherein the second heat treatment is performed for 5 to 70 minutes.

16. An electromagnetic shielding material, comprising:
the Fe-based soft magnetic alloy of claim 1.

17. The material of claim 16, wherein the Fe-based soft magnetic alloy is manufactured by laminating a single or multiple layers of ribbon sheets divided into multiple pieces.

18. (canceled)
